(19) United States
(12) Patent Application Publication
(10) Pub. No.: US 2002/0138846 A1
(43) Pub. Date: Sep. 26, 2002

(54) Communication system

(76) Inventors: Masami Mizutani, Kawasaki (JP); Yasuhiro Kawakatsu, Kawasaki (JP); Eishi Morimatsu, Kawasaki (JP)

Correspondence Address: KATTEN MUCHIN ZAVIS ROSENMAN, 575 MADISON AVENUE, NEW YORK, NY, 10022-2585, US

(21) Appl. No.: 09/918,273

(22) Filed: Jul. 30, 2001

(30) Foreign Application Priority Data
Jan. 11, 2001 (JP) 2001-003984

(51) Int. Cl. H04N 7/16; H04L 1/22; H04B 1/74; H02H 3/05; H05K 10/00; H03K 19/003; H04N 7/173

(52) U.S. Cl. 725/93; 725/90; 725/116; 725/117; 714/48; 714/15

(57) ABSTRACT

A communication system whereby media quality can be measured with high accuracy and can be properly reflected in the calculation of charges, thus making it possible to provide a high-efficiency information delivery service. Delivery unit controls the delivery of a media stream. Accounting control unit performs accounting control based on media quality information transmitted from a subscriber side, and authentication unit authenticates a device which is to receive the media stream. Receiving unit controls the reception of the media stream, and connection information management unit manages connection information for specifying the media stream. Media quality measurement control unit controls the measurement of media quality of the specified media stream, generates media quality information and transmits the media quality information to a station.

### BACKGROUND OF THE INVENTION

(1) Field of the Invention

The present invention relates to a communication system, and more particularly, to a communication system enabling communications between a subscriber and a station.

(2) Description of the Related Art

In recent years, digital compression of video and multimedia contents typified by VOD (Video-On-Demand) have become popular, making it possible to enjoy video information services easily and economically.

Ordinary broadcasts, as opposed to such services, can be received and viewed by anyone by just having a receiver installed, while CATV, some satellite broadcasting and video view services using the Internet adopt a chargeable broadcast system wherein a program can be viewed by only those subscribers who pay to see the program.

A charging method for chargeable broadcasts generally includes a flat-fee system in which a fixed amount of charge for a prescribed term is collected from subscribers, and a pay-per-view system in which a certain charge is set for each program and subscribers are charged for the programs which they viewed. Conventionally, in either system, no proper amount is refunded to subscribers in the event the picture quality is degraded due to an accident on the transmission line.

According to a conventional technique disclosed in Unexamined Japanese Patent Publication No. 9-130387, for example, loss of cells in an ATM network is measured, the measurement result is regarded as data quality, and degradation of the picture quality is reflected in the calculation of charges to be collected from subscribers.

However, this conventional technique is low in flexibility because the data quality via a specific network can only be reflected in the calculation of charges. Also, the measurement performed is not on an end-to-end basis, and thus a problem arises in that the data quality cannot be measured with accuracy.

FIG. 18 shows an outline of the conventional technique. An ATM network 100 is connected with ATM switches 101 and 102. A delivery device 104 of a station side is connected to the ATM switch 102, while a receiving device 103 at a subscriber's home is connected to the ATM switch 101. Information such as video data is transmitted from the delivery device 104 to the receiving device 103 through the ATM switch 102, the ATM network 100, and the ATM switch 101.

In the conventional technique, a difference between the number of cells that flowed into the ATM network 100 and the number of cells that flowed out of the network is regarded as data quality, which is then converted into service quality. Accordingly, the application of the conventional technique is limited to ATM network and it is not possible to apply the technique to a network constructed by multiple stages of diverse networks, such as the Internet. Also, since the quality measurement performed is not end-to-end measurement from the delivery device 104 to the receiving device 103, the data quality cannot be measured with accuracy.

### SUMMARY OF THE INVENTION

The present invention was created in view of the above circumstances, and an object thereof is to provide a communication system whereby media quality can be measured with high accuracy and can be properly reflected in the calculation of charges, thus making it possible to provide a high-efficiency information delivery service.

To achieve the above object, there is provided a communication system enabling communications between a subscriber and a station. The communication system comprises a delivery device installed on a station side and including delivery means for controlling delivery of a media stream, accounting control means for performing accounting control based on media quality information transmitted from a subscriber side and authentication means for authenticating a device which is to receive the media stream, and a terminal device installed on the subscriber side and including receiving means for controlling reception of the media stream, connection information management means for managing connection information for specifying the media stream, and media quality measurement control means for controlling measurement of media quality of the specified media stream, generating the media quality information and transmitting the generated media quality information to the station.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a diagram illustrating the principle of a communication system according to the present invention;

FIG. 2 is a diagram showing the structure of a media stream;

FIG. 3 is a diagram showing an outline of first media quality measurement control;

FIG. 4 is a diagram showing media quality information;

FIG. 5 is a block diagram illustrating extraction of lost data and recovery of quality;

FIG. 6 is a diagram showing algorithm identifiers;

FIG. 7 is a diagram showing lost data information;

FIG. 8 is a diagram illustrating the recovery of quality;

FIG. 9 is a diagram showing a sequence of pictures on stream and a replay sequence;

FIG. 10 is a diagram showing an example of how a degradation index is calculated in the case of error in I1 picture;

FIG. 11 is a diagram showing an example of how the degradation index is calculated in the case of error in P4 picture;

FIG. 12 is a diagram showing an example of how the degradation index is calculated in the case of error in B2 picture;

FIG. 13 is a diagram showing an example of how the degradation index is calculated in the case of error in the I1 and P4 pictures;

FIG. 14 is a diagram showing an example of how the degradation index is calculated in the case of error in the B2 and B5 pictures;

FIG. 15 is a diagram showing an example of accounting control;

FIG. 16 is a diagram showing subunits into which one media unit is divided;

FIG. 17 is a diagram showing an outline of a second modification; and

FIG. 18 is a diagram showing a conventional technique.

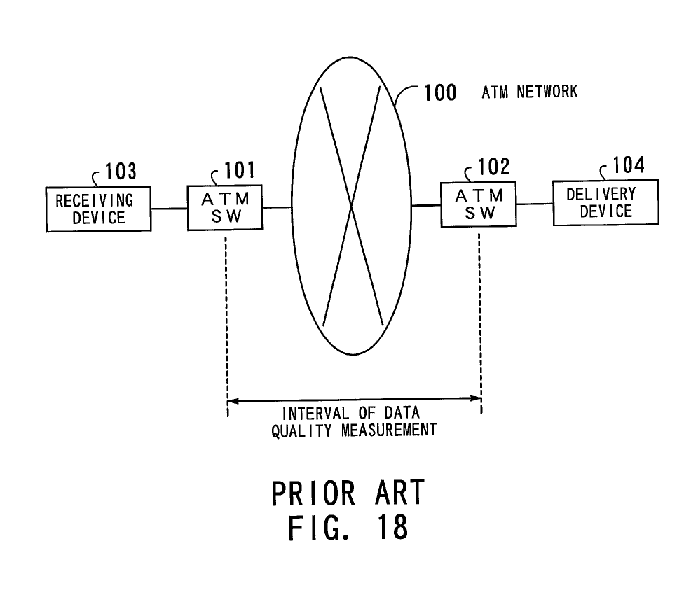

### DESCRIPTION OF THE PREFERRED EMBODIMENTS

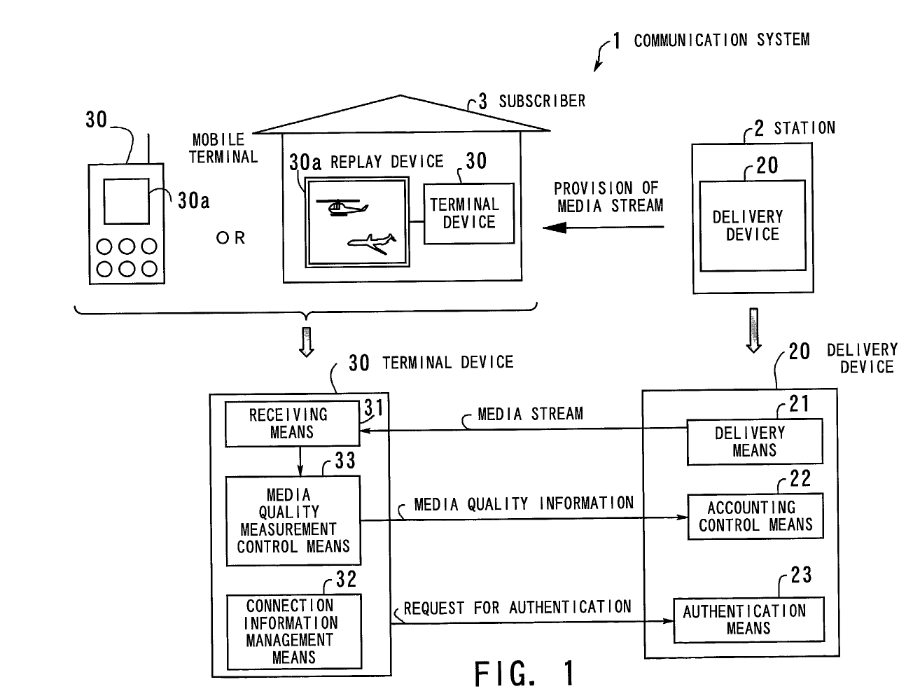

An embodiment of the present invention will be hereinafter described with reference to the drawings. FIG. 1 illustrates the principle of a communication system according to the present invention. The communication system 1 of the present invention comprises a delivery device 20 installed in a station 2, and a terminal device 30 installed in a subscriber's home 3 (or provided as a mobile terminal) and connected with a replay device 30a. The terminal device 30 can be used with multiple replay software installed therein, and also a plurality of replay devices 30a may be installed.

In the delivery device 20, delivery means 21 controls the delivery of a media stream to the subscriber 3. The media stream denotes a stream of multimedia data (including control information) such as video and sound.

Accounting control means 22 performs accounting control (including money payback etc.) based on media quality information, described later, transmitted from the subscriber 3. Authentication means 23 authenticates a device (terminal device 30 or replay device 30a) which is to receive the media stream.

In the terminal device 30, receiving means 31 controls the reception of the media stream. Connection information management means 32 manages connection information for specifying the media stream.

The connection information includes the IP address of the terminal device 30, UDP (User Datagram Protocol), port number, session ID, etc. The connection information management means 32 determines the connection information at the start of a view service through negotiations between the delivery device 20 and the terminal device 30, and retains the determined connection information. Such control includes exchange of information whereby a service provider from which the media stream is to be received can be specified.

In cases where a plurality of replay devices 30a are installed to receive multiple view services, the connection information management means 32 can set and manage multiple sets of connection information.

Media quality measurement control means 33 performs at least one of first and second media quality measurement control to generate media quality information and transmits the generated information to the station 2. The media quality measurement control signifies control for measuring the degree to which a media stream transmitted from the delivery device 20 was degraded during transmission through the network.

In the first media quality measurement control, the media quality of the media stream specified by the connection information management means 32 is measured by detecting a packet with a loss of data based on the continuity of packets. In the second media quality measurement control, the media quality is measured by calculating a degradation index indicative of a degree of degradation of each media unit, as described in detail later.

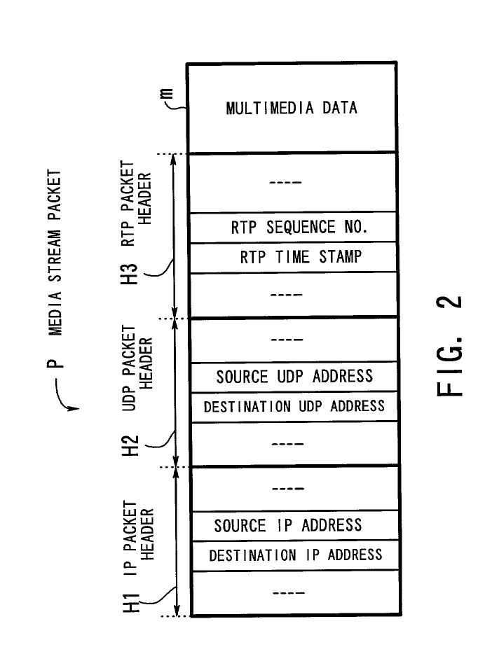

The structure of a media stream will be now described with reference to FIG. 2. The figure shows a UDP packet structure of a media stream on the Internet.

A media stream packet P is constituted by an IP packet header H1, a UDP packet header H2, an RTP (Real-time Transport Protocol) packet header H3, and multimedia data m. RTP is a Transport layer protocol for transmitting/receiving video and sound in real time.

The IP packet header H1 includes a destination IP address and a source IP address, the UDP packet header H2 includes a destination UDP address and a source UDP address, and the RTP packet header H3 includes an RTP time stamp and an RTP sequence number. The multimedia data m is video/sound data which is decoded and actually viewed/listened by the subscriber 3.

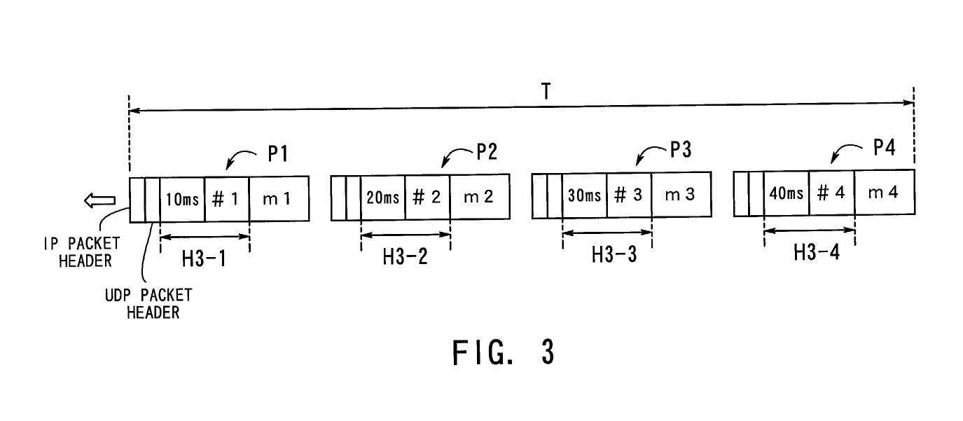

The first media quality measurement control by the media quality measurement control means 33 will be now described. FIG. 3 shows an outline of the first media quality measurement control. The terminal device 30 receives packets of the media stream. In the illustrated example, the media quality is measured with respect to packets P1 to P4 during a media quality measurement time T.

The packets P1 to P4 are each affixed with an IP packet header and a UDP packet header. Also, the packets respectively include, as RTP packet headers H3-1 to H3-4, RTP time stamps “10 ms”, “20 ms”, “30 ms” and “40 ms” (RTP time stamp t indicates that the data of the packet to which the time stamp t is affixed is displayed after a lapse of t from the start of replay) and RTP sequence numbers “#1” to “#4”. Further, multimedia data m1 to m4 are affixed to the respective packets.

When the packets of the media stream have been normally transmitted over the network as illustrated, the RTP sequence numbers retain continuity. The media quality measurement control means 33 can therefore detect a lost packet by monitoring the continuity of packets all the time.

The RTP sequence number is a number recurring in a range of “#0” to “#65535”, and accordingly, the continuity cannot be accurately monitored by means of the RTP sequence number alone. For example, when the packet P3 has been lost, it is not possible to determine solely by the RTP sequence number whether the third packet or the (65536+2)th packet has been lost.

Accordingly, the media quality measurement control means 33 uses both the RTP time stamp and the RTP sequence number to monitor the continuity of packets. For example, if a packet P(a, t) (a: sequence number; t: time stamp) is followed by a packet P(b, s), it can be concluded that at least (b−a+1) packets are missing.

The media quality may be measured for only a limited time during session by evaluating the time stamps of the RTP packet headers.

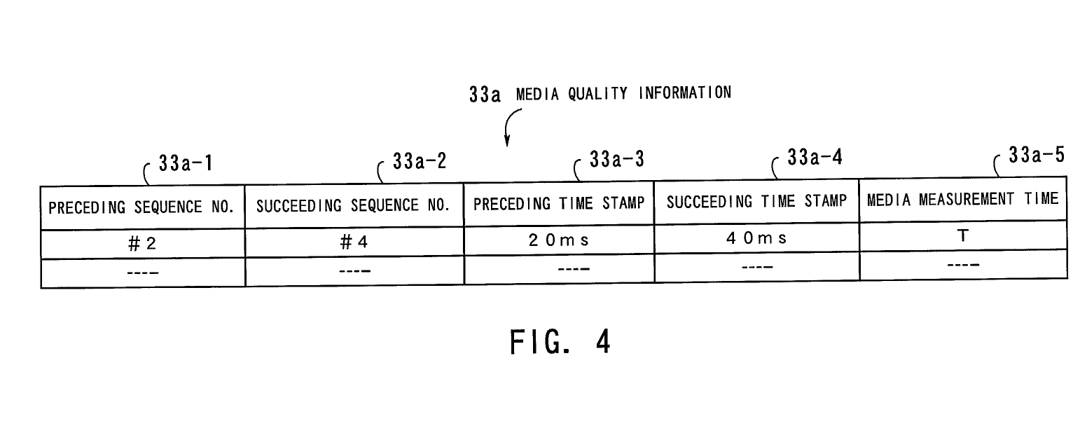

FIG. 4 shows the media quality information. The media quality information 33a is constituted by a preceding sequence number 33a-1, a succeeding sequence number 33a-2, a preceding time stamp 33a-3, a succeeding time stamp 33a-4, and a media measurement time 33a-5.

If the packet P3 shown in FIG. 3, for example, was lost, the media quality information 33a includes “#2” as the preceding sequence number 33a-1, “#4” as the succeeding sequence number 33a-2, “20 ms” as the preceding time stamp 33a-3, “40 ms” as the succeeding time stamp 33a-4, and “T” as the media measurement time 33a-5.

On receiving the media quality information 33a, the accounting control means 22 calculates a charge based on the media quality. In cases where degradation of the picture quality or the like occurred, a proper amount of money is paid back to the subscriber 3.

In the first media quality measurement control, a lost packet is detected to measure the media quality and the media quality information is generated. When measuring the quality, an amount of delay for which the packets delayed in reaching the terminal device 30, for example, may also be included in the media quality information.

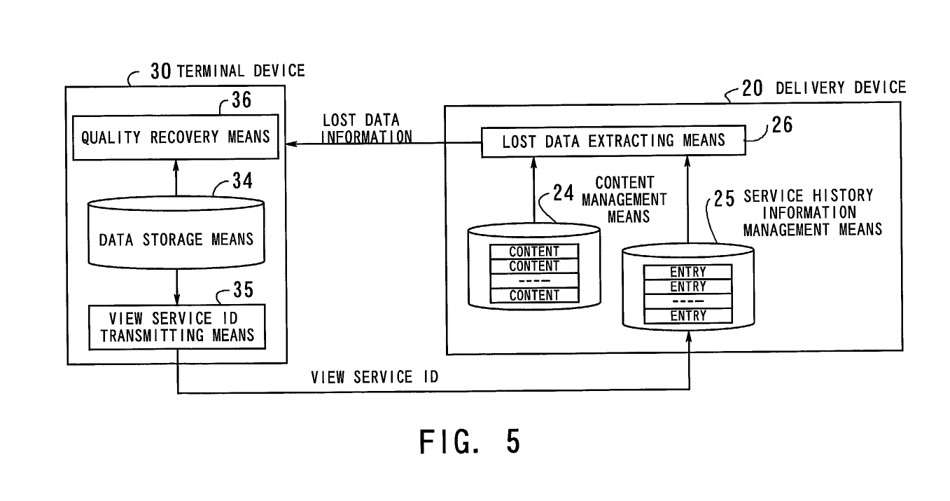

The following describes the construction and operation for the extraction of lost data in the delivery device 20 and the recovery of quality in the terminal device 30. FIG. 5 is a block diagram illustrating the extraction of lost data and the recovery of quality.

Data storage means 34 of the terminal device 30 stores data (delivered multimedia data, media quality information, etc.) necessary for the recovery of quality. View service ID transmitting means 35 transmits a view service ID of multimedia data whose quality needs to be recovered, to the delivery device 20.

Quality recovery means 36 receives lost data information transmitted from the delivery device 20, and recovers the quality of the multimedia data which is stored in the data storage means 34 and of which the quality needs to be recovered.

Content management means 24 of the delivery device 20 stores and manages contents of multimedia data. Service history information management means 25 manages service history information associated with individual entries. Also, the service history information management means 25 receives the view service ID and transmits the service history information about the performed service to lost data extracting means 26. Based on the service history information, the lost data extracting means 26 extracts lost data from the corresponding content, and transmits the lost data information to the terminal device 30.

The operation will be now described. After view service, the view service ID transmitting means 35 of the terminal device 30 acquires the view service ID of multimedia data whose quality needs to be recovered, from the data storage means 34 and transmits the acquired ID to the delivery device 20.

Using the received view service ID as a key, the service history information management means 25 acquires information relevant to the performed view service. Each entry of the service history information management means 25 includes the view service ID, viewer account, terminal device ID, replay device ID, algorithm identifier used when packetizing the multimedia data, initial value of the sequence number, time scale of the time stamp, content identifier, media quality information, amount applicable to degraded quality (amount reduced based on the notified media quality), etc.

The viewer account, terminal device ID and replay device ID are used for the purpose of authentication when the quality recovery service is performed. The content identifier is used to identify the title of the delivered multimedia data.

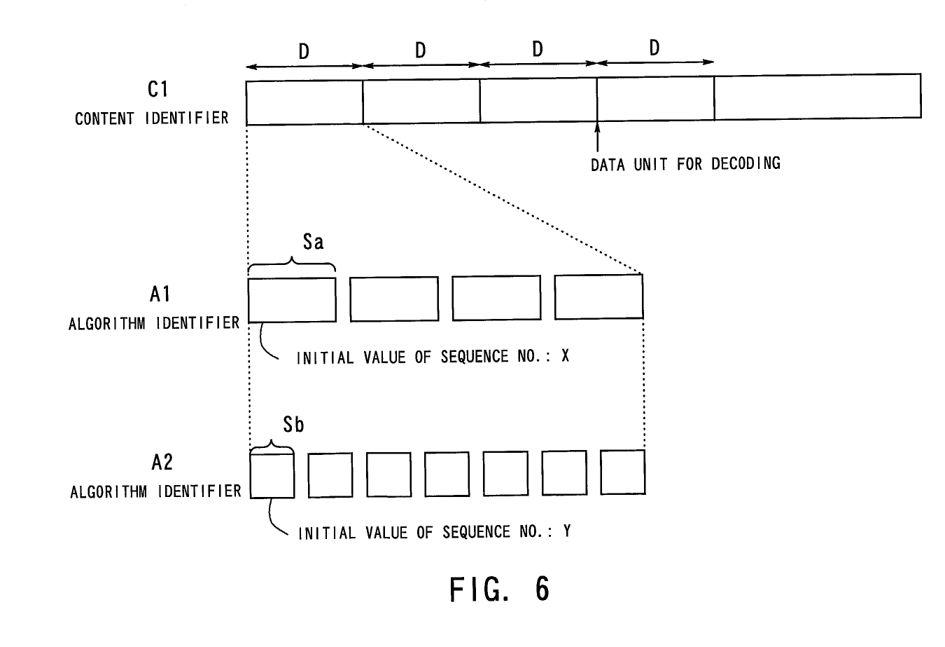

FIG. 6 shows algorithm identifiers. Let it be assumed, for example, that multimedia data with a content identifier C1 is segmented into data units D for decoding.

In this case, an algorithm identifier A1 subdivides each data unit D into segments of size Sa when packetizing the data. Also, an algorithm identifier A2 subdivides each data unit D into segments of size Sb (Sb<Sa) when packetizing the data.

Thus, the algorithm identifiers are each an identifier indicative of the size in accordance with which multimedia data is packetized. For example, the algorithm identifier A1 indicates a packet segment size used when multimedia data is delivered to cable television users, and the algorithm identifier A2 (smaller in packet size than the algorithm identifier A1) indicates a packet segment size used when multimedia data is delivered to mobile telephone users.

To packetize multimedia data, multimedia data may be packetized into data units of fixed size, as described above, or may be packetized depending upon a method of encoding the multimedia data. The initial value of the sequence number denotes a sequence number assigned to the first packet obtained by packetizing the multimedia data.

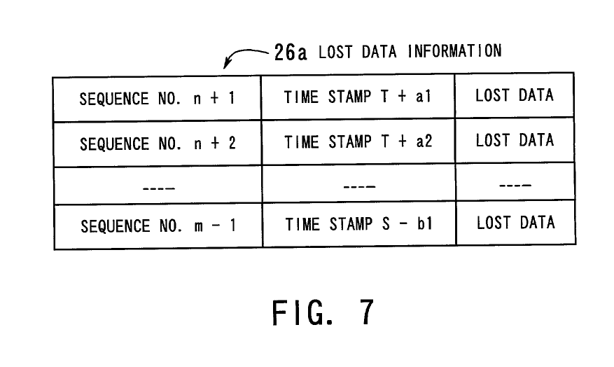

FIG. 7 shows the lost data information. The lost data extracting means 26 can specify lost part (byte position and byte size as counted from the beginning) of the multimedia data (stored and managed by the content management means 24) specified by the content identifier, based on the media quality information, the initial value of the sequence number and the algorithm identifier. Thus, the lost data extracting means 26 generates lost data information 26a by affixing a sequence number and a time stamp value to the lost part of data, and transmits the generated information to the terminal device 30.

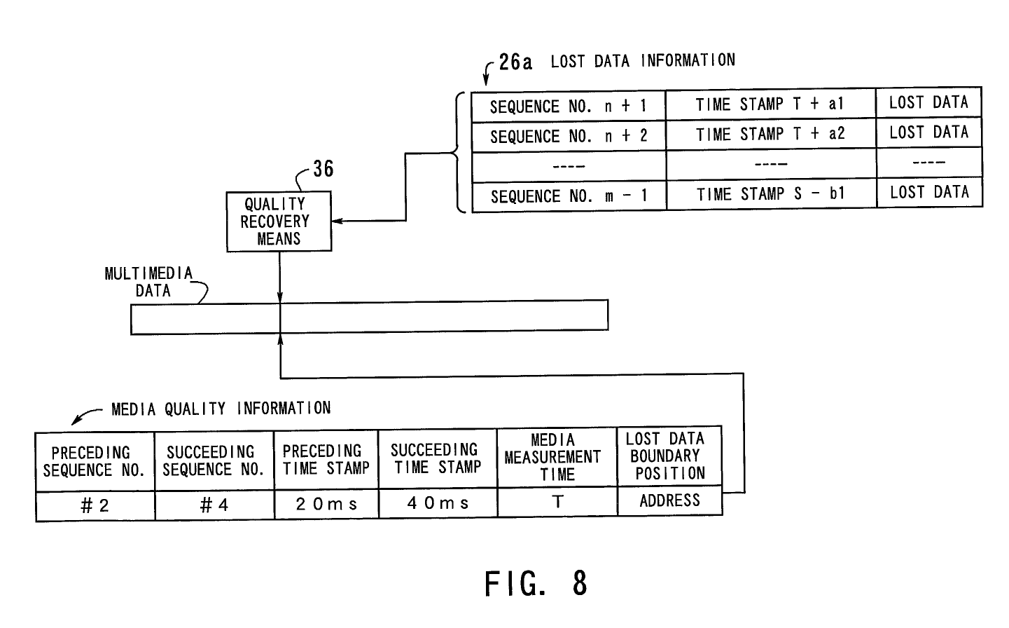

The recovery of quality of lost multimedia data will be now described with reference to FIG. 8. To make use of the lost data information for the recovery process, the data storage means 34 stores multimedia data to be recovered, corresponding media quality information, and lost data boundary position. The lost data boundary position represents an address of memory storing the multimedia data where the lost data is to be inserted.

The quality recovery means 36 recovers the quality of the multimedia data based on the aforementioned data necessary for the quality recovery and stored in the data storage means 34 and the lost data information 26a transmitted from the delivery device 20.

In this manner, the terminal device 30 requests the delivery device 20 to provide a quality recovery service for stored multimedia data. In the delivery device 20, using the service history information, the lost data extracting means 26 extracts lost part of data based on the media quality information, and transmits the extracted data to the terminal device 30. Then, in the terminal device 30, the quality recovery means 36 recovers the quality of the stored multimedia data by using the received lost data information 26a. This makes it possible to carry out highly serviceable delivery control for multimedia data.

When the quality recovery service is requested from the terminal device 30, an amount of money once paid back to the viewer because of poor quality may be again added by the accounting control means 22 to the charge stored in the corresponding entry of the service history information management means 25.

The second media quality measurement control by the media quality measurement control means 33 will be now described. In the second media quality measurement control, a degradation index indicative of a degree of degradation of each media unit is calculated to measure the media quality and is transmitted to the delivery device 20 as the media quality information. Specifically, this control is applied to MPEG video.

Also, in the present invention, the MPEG media units signify I picture (intraframe coded image), P picture (interframe forward prediction coded image) and B picture (two-way prediction coded image) in MPEG.

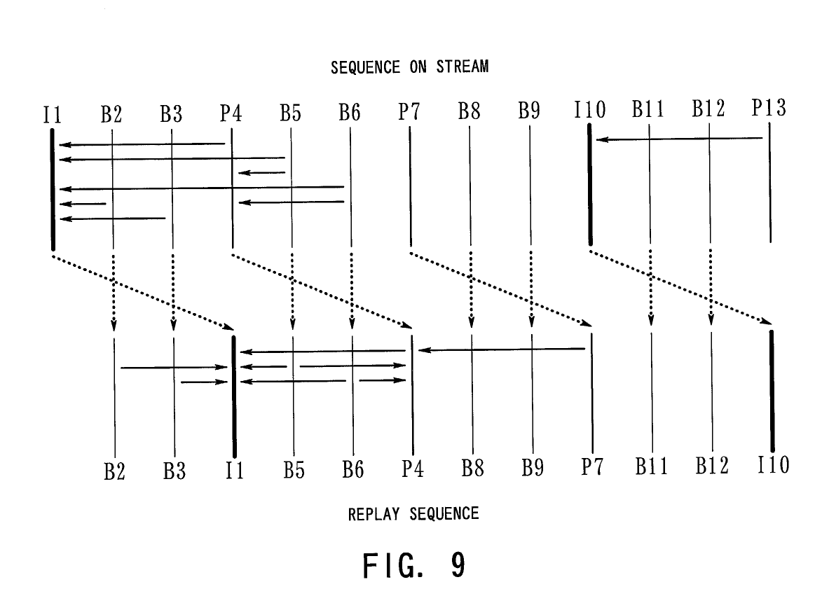

FIG. 9 shows a sequence of pictures on stream and a replay sequence of pictures. In the following, a B picture with the picture number “5” is indicated at B5, and other pictures are also indicated in like manner. As shown in the figure, the sequence of pictures on the stream (sequence of coded pictures on transmission media) differs from the replay sequence of the pictures. Also, the solid-line arrows indicate reference frames used for the replay. For example, the B5 picture uses the I1 and P4 pictures as reference frames. In the figure, solid-line arrows indicating the reference frames of B8, B9, B11 and B12 are omitted.

In the illustrated sequence of pictures, if error has occurred in a picture which is referred to as a reference picture, error occurs also in a picture being replayed, causing a situation where the picture being replayed can be affected by an error of the picture which is later in the replay sequence.

In practice, however, since the sequence of pictures on the stream is different as shown in the figure, only an error that occurred in a picture earlier in time affects the picture being replayed. Accordingly, in the present invention, the degree of influence of propagation of error that occurred on the stream earlier in time than the picture being replayed is cumulated to calculate a degradation index.

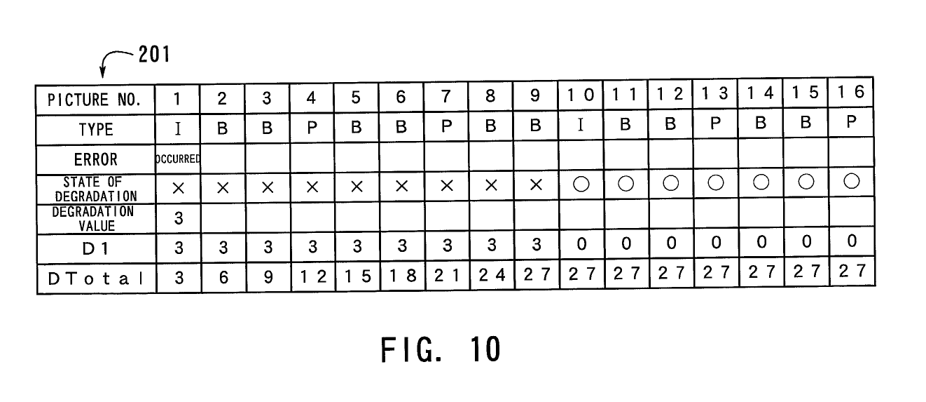

The following describes specific examples of how the degradation index is calculated when error has occurred in a picture. FIG. 10 shows an example of calculating the degradation index in the case of error in the I1 picture. A degradation value is set to “3” if error has occurred in I picture, set to “2” if error has occurred in P picture, and set to “1” if error has occurred in B picture. The degradation value is “0” if no error has occurred.

Also, D1 represents a degradation count which is the sum of the degradation value of a reference picture and the degradation value of a picture in question, and DTotal represents a cumulative degradation value obtained by cumulating the D1 values. In this example, the degradation index is the DTotal of the picture measured last in the media quality measurement range.

In the illustrated case 201 where error has occurred in the I1 picture, the degree of influence of error propagation is such that the error is propagated up to the B9 picture, and the succeeding I10 to P16 pictures are not affected by the error.

Consequently, in this case, the degradation value “3” is cumulatively added up from the I1 picture through the B9 picture, while the degradation value of the I10 to P16 pictures is “0”. Thus, the DTotal value of the P16 picture is “27”, and this means that the degradation index of the I1 to P16 pictures is “27”.

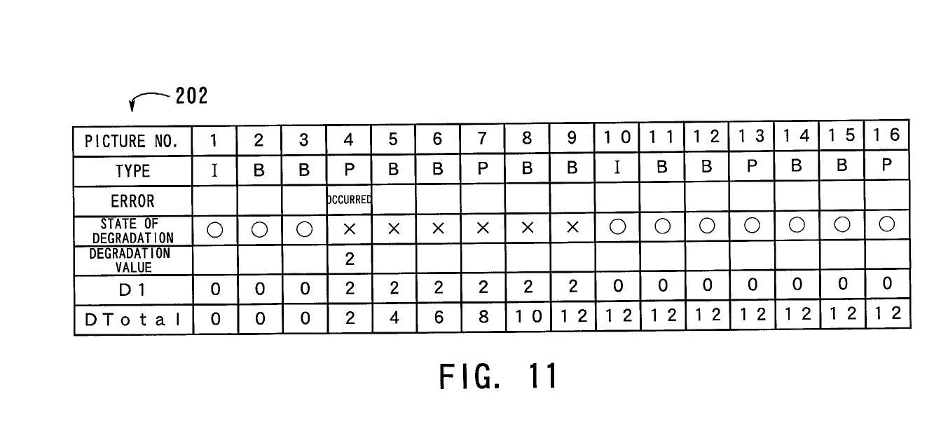

FIG. 11 shows an example of how the degradation index is calculated when error has occurred in the P4 picture. In the illustrated case 202 where error has occurred in the P4 picture, the degree of influence of error propagation is such that the P4 to B9 pictures are affected by the error. The error neither affects the I1 to B3 pictures, nor is propagated to the I10 to P16 pictures following the B9 picture.

Accordingly, in this example, the degradation value of the I1 to B3 pictures is “0”, the degradation value “2” is cumulatively added up from the P4 to B9 pictures, and the degradation value of the I10 to P16 pictures is “0”. Thus, the DTotal value of the P16 picture is “12”, indicating that the degradation index of the I1 to P16 pictures is “12”.

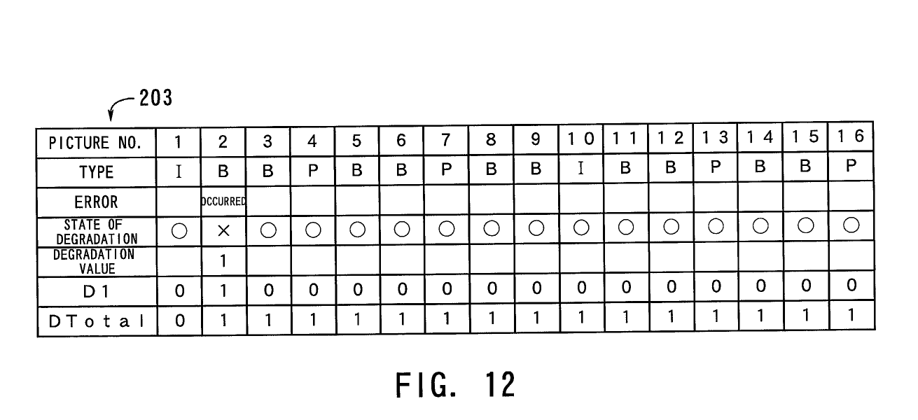

FIG. 12 shows an example of how the degradation index is calculated when error has occurred in the B2 picture. In the illustrated case 203 where error has occurred in the B2 picture, the degree of influence of error propagation is such that the B2 picture alone is affected by the error. The error neither affects the I1 picture, nor is propagated to the B3 to P16 pictures following the B2 picture.

Accordingly, in this example, the degradation value of the I1 picture is “0”, the degradation value of the B2 picture is “1”, and the degradation value of the B3 to P16 pictures is “0” because the error is not propagated to these pictures. Thus, the DTotal value of the P16 picture is “1”, and therefore, the degradation index of the I1 to P16 pictures is “1”.

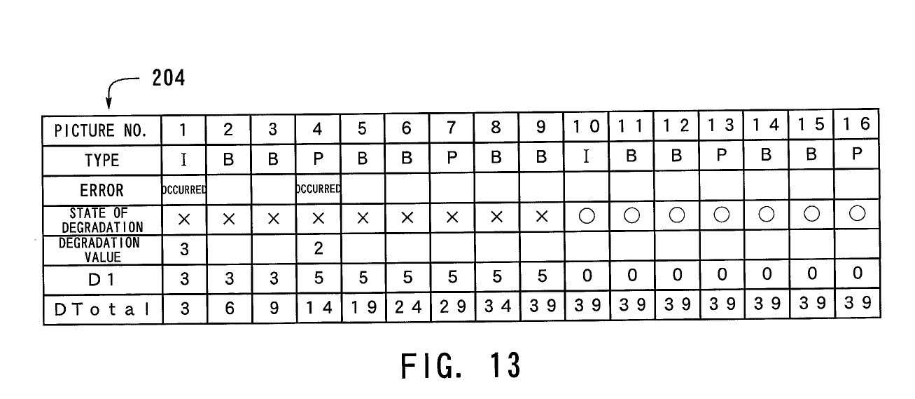

FIG. 13 shows an example of how the degradation index is calculated when error has occurred in the I1 and P4 pictures. In the illustrated case 204 where error has occurred in the I1 and P4 pictures, the degree of influence of error propagation is such that the error of the I1 picture is propagated to the B2, B3 and P4 pictures, and that the error of the P4 picture is propagated to the B5 to B9 pictures. The following I10 to P16 pictures are not affected by the error.

Accordingly, in this example, the degradation value “3” is cumulatively added up from the I1 to B3 pictures, and the degradation value “5” (=P4 picture degradation value “2”+I1 picture degradation value “3”) is cumulatively added up from the P4 to B9 pictures. The degradation value of the I10 to P16 pictures is “0” since the error is not propagated to these pictures. Consequently, the DTotal value of the P16 picture is “39”, and this means that the degradation index of the I1 to P16 pictures is “39”.

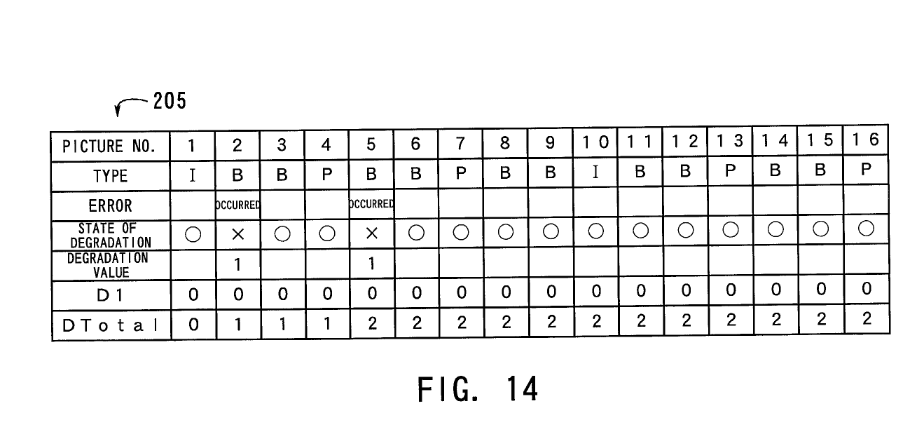

FIG. 14 shows an example of how the degradation index is calculated when error has occurred in the B2 and B5 pictures. In the illustrated case 205 where error has occurred in the B2 and B5 pictures, the degree of influence of error propagation is such that the B2 and B5 pictures alone are affected by the respective errors. The I1 picture is not affected by the error, and the error is propagated neither to the B3 and P4 pictures nor to the B6 to P16 pictures.

Accordingly, in this example, the degradation value of the I1 picture is “0”, and the degradation value “1” of the B2 picture and the B5 picture is cumulatively added up, while the degradation value of the B3 and B4 pictures and the B6 to P16 pictures is “0” because no error is propagated to these pictures. Consequently, the DTotal value of the P16 picture is “2”, indicating that the degradation index of the I1 to P16 pictures is “2”.

Thus, in the second media quality measurement control, the degradation index of pictures is calculated based on the degree of influence of error propagation, and the calculated degradation index is transmitted to the delivery device 20 as the media quality information. On receiving the media quality information, the accounting control means 22 calculates a charge corresponding to the media quality. This permits a proper amount of money to be paid back to the subscriber 3 in the event degradation of picture quality or the like has occurred.

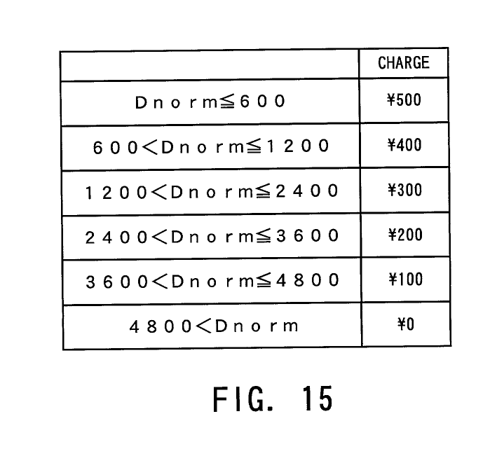

FIG. 15 shows an example of the accounting control, wherein a charge is calculated per program. Since different programs have different lengths, DTotal measured from the beginning through to the end of a program is normalized with respect to the program length. In this example, DTotal is normalized to an average degree of degradation per hour, according to Dnorm=DTotal/(length*60), where length is the length of a program and the unit is in minutes.

Using Dnorm, the charge is adaptively varied as shown in the table of FIG. 15. In the illustrated example, ¥500 is charged if the program was replayed with no substantial degradation, and the program is free of charge if it was extremely degraded.

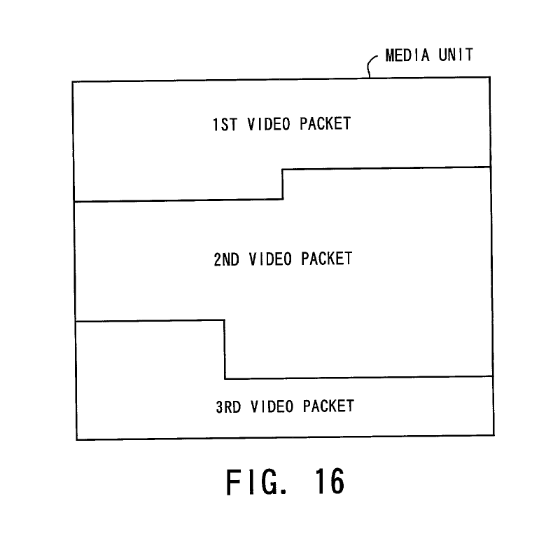

Modifications of the second media quality measurement control will be now described. According to a first modification, the degradation index is calculated with respect to each of subunits into which a media unit is divided. FIG. 16 shows such subunits into which one media unit is divided.

In the case of a video stream compressed according to MPEG4, for example, one media unit is divided into a plurality of video packets. The figure shows the division of a media unit into three video packets. By obtaining the degradation degree with respect to each of the subunits, it is possible to evaluate the quality with higher accuracy.

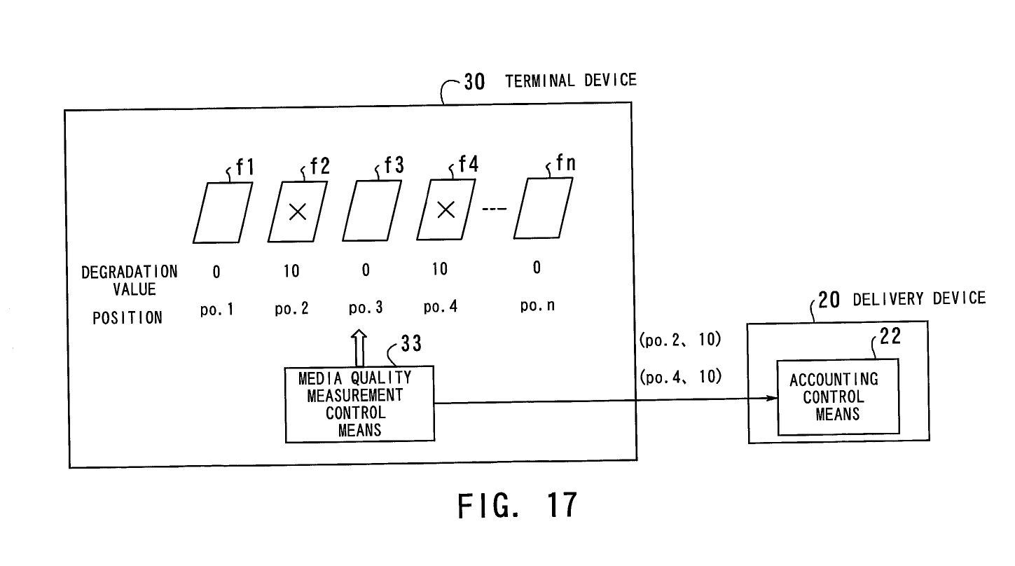

A second modification takes account of position information indicative of the position of a degraded media unit, in addition to the degradation index. FIG. 17 shows an outline of the second modification. The media quality measurement control means 33 measures a degradation index of media that underwent frame degradation, and also detects position information thereof. The degradation index and the position information are transmitted to the delivery device 20 as the media quality information. On receiving the media quality information, the accounting control means 22 calculates a charge based on the degradation index and the position information.

For example, let it be assumed that, in a media stream of frames f1 to fn received by the terminal device 30, the media quality measurement control means 33 has detected degradation of frames at frame positions “po. 2” and “po. 4”, and also measured “10” as their degradation value. In this case, the media quality measurement control means 33 transmits media quality information (po. 2, 10), (po. 4, 10) including the position information and the degradation value to the delivery device 20.

On receiving the media quality information, the accounting control means 22 causes a degree of importance of the degraded media unit to be reflected in the calculation of a charge with reference to the position information (The degree of importance mentioned here means the extent to which the viewer is satisfied with the delivered media; for example, a media unit has a high degree of importance if the viewer will feel dissatisfied with the media when the media is degraded only slightly, and has a low degree of importance if the viewer will not be very dissatisfied with the media even when the media is considerably degraded).

Specifically, if it is judged that the frame f4 at the frame position “po. 4” has a higher degree of importance than the frame f2 at the frame position “po. 2” (for example, the frame f2 is a still image of a motionless scene while the frame f4 is a dynamic image of a person full of motion), an amount of reduction on the frame f4 is calculated to be larger than that on the frame f2 even though the degradation values of these frames are both “10”.

Similarly, in the case where (po. 2, 40) and (po. 4, 5) and if the degree of importance of the frame f4 is higher than that of the frame f2, the accounting control is performed such that an amount of reduction on the frame f4 is set larger than that on the frame f2, though the degradation value of the frame f4 is smaller than that of the frame f2. The degree of importance of each media unit is set beforehand in association with the corresponding position information.

Thus, not only the degradation index but the position information of a degraded frame are transmitted to the delivery device 20 as the measured media quality, and the delivery device 20 calculates a charge taking account of the degree of importance derived based on the position information. This makes it possible to calculate a charge linearly related with the viewer's subjective evaluation.

Authentication control of the terminal device 30 will be now described. On connecting to the network, the terminal device 30 transmits a request for authentication to the authentication means 23 of the delivery device 20. At this time, the terminal device 30 transmits its own terminal device ID for identification.

On receiving the terminal device ID transmitted from the terminal device 30, the authentication means 23 collates the terminal device ID with a device list ID prepared beforehand. If, as a result of the collation, the terminal device ID is found to be valid, the authentication means 23 transmits a response notifying the establishment of authentication to the terminal device 30. After the reception of information indicative of the establishment of authentication, the individual means constituting the terminal device 30 can perform respective functions. The authentication may be carried out at any desired timing insofar as the delivery of multimedia data is not yet started.

There is a risk of unlawful media quality information being forged at the terminal device 30 so that a charge for a view service, calculated by the delivery device 20, may be willfully modified.

In view of this, the media quality measurement control means 33 encrypts the media quality information (by means of public key encryption etc.) before transmitting the same, to prevent the media quality information from being tapped or falsified and to enable only a specified delivery device 20 to read the information.

For example, while negotiating with the delivery device 20 about view service, the terminal device 30 acquires a public encryption key published by the authentication means 23.

When transmitting the measured media quality information to the delivery device 20, the media quality measurement control means 33 encrypts the information with the use of the public key prior to transmission. The authentication means 23 decrypts the received media quality information by using the public key. This makes it possible to perform high-secrecy communication control.

As described above, the communication system 1 of the present invention is advantageous in that from the standpoint of the view service provider, it is possible to deepen the subscribers' satisfaction since charges are calculated based on the view quality, and that from the standpoint of the subscriber, the subscriber does not feel unjust even if the view quality varies from service to service since the view quality is reflected in the charges.

Conventionally, in cases where while multimedia data is delivered in time sequence, a part including the subscriber's desired information is degraded in view quality, the subscriber has no choice but to again receive the multimedia data or to purchase expensive content. According to the present invention, by contrast, the quality recovery service allows the subscriber to obtain such information efficiently at a reasonable price.

Also, the position information of a degraded frame is transmitted together with the measured degradation index to the service provider, and thus the service provider can calculate charges by not only allowing degradation caused on the transmission line to be reflected in the charges but taking account of the subscribers' subjective evaluation (Namely, the accounting control can be performed in a manner such that where the degradation caused is slight but greatly impairs the viewer's satisfaction, a large reduction of charge is made even if the calculated degradation value is small).

Further, when initiating communications between the terminal device 30 and the delivery device 20, proper authentication control is performed, thus permitting high-secrecy communications.

The communication system 1 of the present invention can be applied to a wide range of systems which are designed to deliver multimedia data such as video and music and have an accounting control function (e.g., in a business field wherein PPV service or the like is provided, a business field wherein view service is provided to mobile telephone terminals which are capable of access to the Internet through a mobile telephone network, a business field wherein content downloading service is provided or contents are sold in the form of CD-ROM, etc.).

As described above, in the communication system according to the present invention, the media quality of a received media stream is measured on the subscriber side to generate media quality information, and the accounting control is performed on the station side in accordance with the media quality information. This permits charges to be calculated properly in accordance with the media quality, whereby high-quality information delivery service can be provided efficiently.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A communication system enabling communications between a subscriber and a station, comprising:
a delivery device installed on a station side, said delivery device including delivery means for controlling delivery of a media stream, accounting control means for performing accounting control based on media quality information transmitted from a subscriber side, and authentication means for authenticating a device which is to receive the media stream; and
a terminal device installed on the subscriber side, said terminal device including receiving means for controlling reception of the media stream, connection information management means for managing connection information for specifying the media stream, and media quality measurement control means for controlling measurement of media quality of the specified media stream, generating the media quality information and transmitting the generated media quality information to the station.

2. The communication system according to claim 1, wherein said media quality measurement control means performs at least one of first media quality measurement control in which a packet with a loss of data is detected by continuity of packets, and second media quality measurement control in which a degradation index of a media unit is calculated.

3. The communication system according to claim 2, wherein said delivery device further includes lost data extracting means for the first media quality measurement control, said lost data extracting means extracting lost data from a media stream content, with reference to the media quality information, and transmitting lost data information to the terminal device.

4. The communication system according to claim 3, wherein said terminal device further includes quality recovery means for receiving the lost data information and recovering quality of the media stream.

5. The communication system according to claim 2, wherein said media quality measurement control means calculates the degradation index of each of subunits into which the media unit is divided, to perform the second media quality measurement control.

6. The communication system according to claim 2, wherein said media quality measurement control means calculates the degradation index based on a degree of influence of error propagation on the media unit, to perform the second media quality measurement control.

7. The communication system according to claim 2, wherein said media quality measurement control means transmits the degradation index and position information of a degraded media unit to the delivery device as the media quality information, to perform the second media quality measurement control.

8. The communication system according to claim 7, wherein said accounting control means causes a degree of importance of the degraded media unit to be reflected in the accounting control, with reference to the received position information.

9. A delivery device for providing a subscriber with information, comprising:
delivery means for controlling delivery of a media stream;
accounting control means for performing accounting control based on media quality information transmitted from the subscriber side; and
authentication means for authenticating a device which is to receive the media stream.

10. A terminal device for receiving information from a station, comprising:
receiving means for controlling reception of a delivered media stream;
connection information management means for managing connection information for specifying the media stream; and
media quality measurement control means for controlling measurement of media quality of the specified media stream, generating media quality information and transmitting the media quality information to the station.
